(19) United States
(12) Patent Application Publication
(10) Pub. No.: US 2012/0199711 A1
(43) Pub. Date: Aug. 9, 2012

(54) DISPLAY SCREEN MOUNTING STRUCTURE

(76) Inventor: Peng-Yuan TSAI, Taoyuan County (TW)

(21) Appl. No.: 13/023,183

(22) Filed: Feb. 8, 2011

(51) Int. Cl. H05K 7/14

(52) U.S. Cl. 248/220.22

(57) ABSTRACT

A display screen mounting structure includes a mounting frame unit comprising a base member for mounting on an upright support, a forked support arm extended from the base member, a connection rod member vertically pivotally mounted in the front end of the forked support arm and a connection plate affixed to the outer end of the connection rod member, and a support frame unit comprising a channel frame fastenable to the connection plate and two cushion members respectively capped on the shoulder plates for stopped against the display screen.

### BACKGROUND OF THE INVENTION

1. Field of the Invention

The present invention relates display screen mounting technology and more particularly, to a display screen mounting structure, which can be conveniently and adjustably mounted on an upright support to support any of different models of display screens.

2. Description of the Related Art

Following fast development of technology, many high-tech electronics and electrical products have been continuously created to improve the living standard of people. Nowadays, computer or notebook computer has been intensively used by people in office as well as at home. Further, a computer system uses a display screen for video display. Further, many advanced thin type display screens, such as LCD display screens and LED display screens have been popularly used to substitute for conventional CRT (cathode ray tube) display screen for the advantages of light, thin and space-saving characteristics. For supporting a thin type display screen on an upright support, a specially designed mounting structure is necessary. However, conventional display screen mounting structures are still not satisfactory in function and have drawbacks as follows:
1. For supporting a different model of thin type display screen, a different upright support or display screen mounting structure must be used. For example, a display screen may have mounting screw holes located on the back wall thereof subject to the pitch of 75 mm×75 nn, 100 mm×100 mm or 200 mm×200 mm for mounting. In consequence, the upright support or display screen mounting structure must have mounting through holes that fit the pitch of the mounting screw holes of the display screen. Thus, different designs of upright support or display screen mounting structure must be provided for selection, increasing the manufacturing cost.
2. When a thin type display screen failed and must be replaced by a new model of display screen, the original upright support or display screen mounting structure must also be replaced by a new upright support or display screen mounting structure to fit the new model of display screen, causing waste of resources.

Therefore, it is desirable to provide a display screen mounting structure, which fits different types of display screens for mounting on an upright support.

### SUMMARY OF THE INVENTION

The present invention has been accomplished under the circumstances in view. It is the main object of the present invention to provide a display screen mounting structure, which can be conveniently and adjustably mounted on an upright support to support any of different models of display screens.

To achieve this and other objects of the present invention, a display screen mounting structure comprises a mounting frame unit for mounting on an upright support, and a support frame unit for fastening to the mounting frame unit to hold a display screen. The mounting frame unit comprises a base member for fastening to an upright support, a support arm perpendicularly extended from the periphery of the base member, an opening defined in the front end of the support arm, a connection rod member vertically pivotally mounted in the opening in the front end of the support arm, and a connection plate fixedly connected to the outer end of the connection rod member outside the support arm. The support frame unit comprises a channel frame fastenable to the connection plate, two shoulder plates respectively symmetrically extended from two opposite lateral sides of the channel frame and adapted for supporting a display screen, and a locating block set mounted in the channel frame between the shoulder plates.

Further, the locating block set comprises two locating blocks fixedly mounted in the channel frame near two distal ends thereof between the shoulder plates. The support frame unit further comprises a connection frame connected between the two locating blocks for the mounting of a display screen. Each locating block has a countersunk hole. The connection frame has a mounting hole located on each of two distal ends thereof and respectively fastened to the countersunk hole of each of the two locating blocks by a respective screw. Subject to the use of the connection frame, a different module of display screen can be supported on the support frame unit.

Further, the shoulder plates have mounting through holes made thereof for fastening to mounting screw holes on the back wall of a display screen with screws. The mounting through holes of the shoulder plates fit different pitch designs of mounting screw holes (such as the pitch of 75 mm×75 mm, the pitch of 100 mm×100 mm as well as the pitch of 200 mm×200 mm).

### BRIEF DESCRIPTION OF THE DRAWINGS

FIG. 1 is an elevational view of a display screen mounting structure in accordance with a first embodiment of the present invention.

FIG. 2 is an exploded view of the display screen mounting structure in accordance with the first embodiment of the present invention.

FIG. 3 corresponds to FIG. 2 when viewed from another angle.

FIG. 4 is a schematic drawing illustrating an application example of the display screen mounting structure in accordance with the first embodiment of the present invention (I).

FIG. 5 is a schematic drawing illustrating an application example of the display screen mounting structure in accordance with the first embodiment of the present invention (II).

FIG. 6 is an exploded view of a display screen mounting structure in accordance with a second embodiment of the present invention.

FIG. 7 is a schematic drawing illustrating an application example of the display screen mounting structure in accordance with the second embodiment of the present invention (I).

FIG. 8 is a schematic drawing illustrating an application example of the display screen mounting structure in accordance with the second embodiment of the present invention (II).

FIG. 9 is an exploded view of a display screen mounting structure in accordance with a third embodiment of the present invention.

FIG. 10 is a schematic drawing illustrating an application example of the display screen mounting structure in accordance with the third embodiment of the present invention (I).

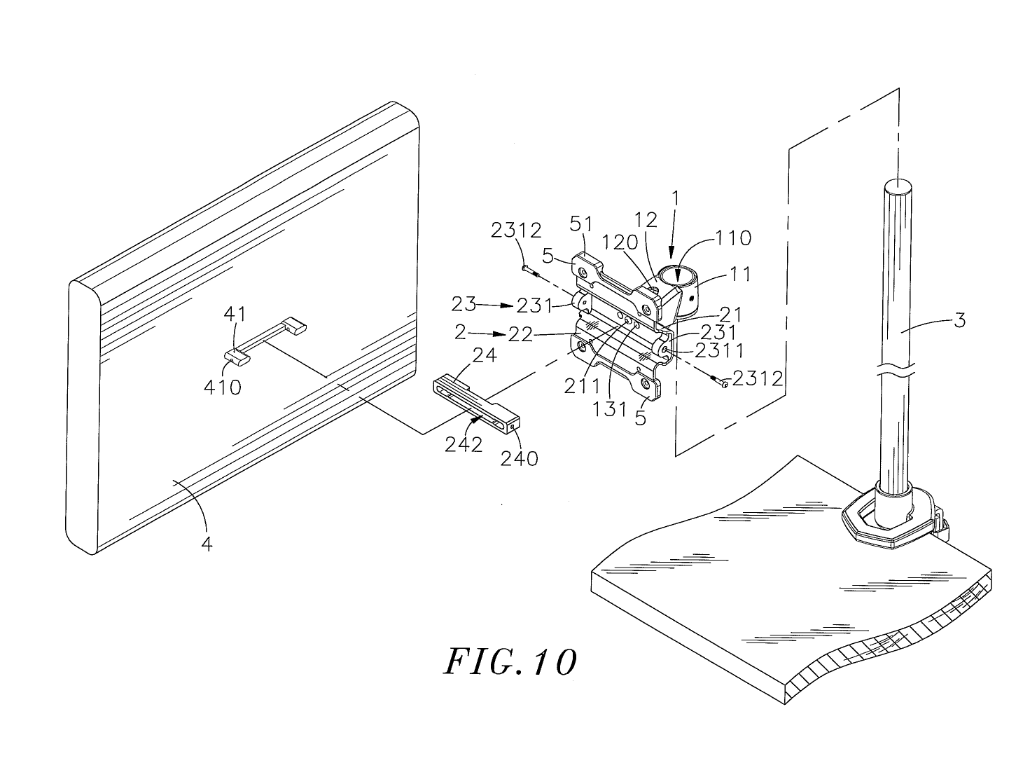

FIG. 11 is a schematic drawing illustrating an application example of the display screen mounting structure in accordance with the third embodiment of the present invention (II).

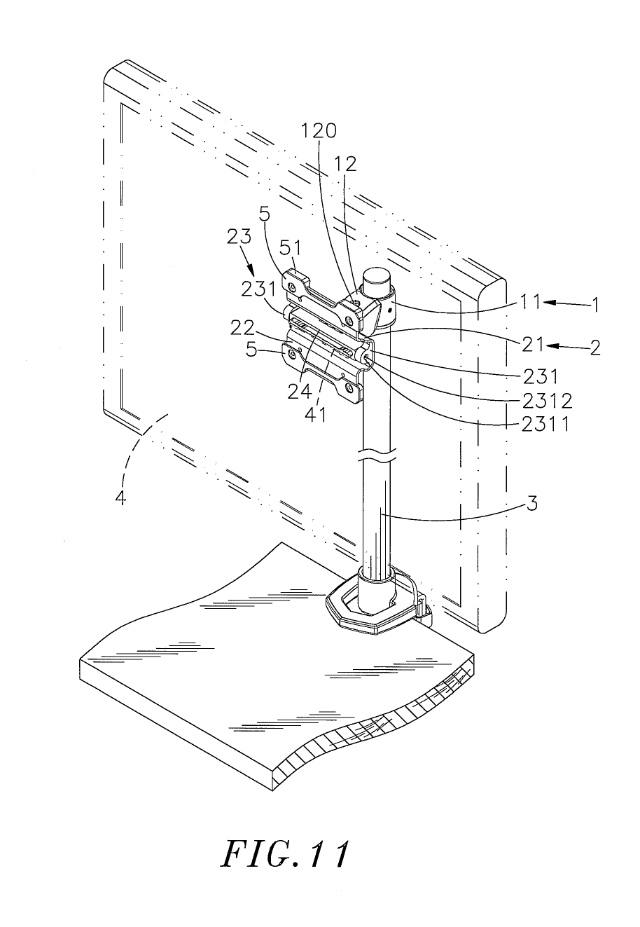

### DETAILED DESCRIPTION OF THE PREFERRED EMBODIMENT

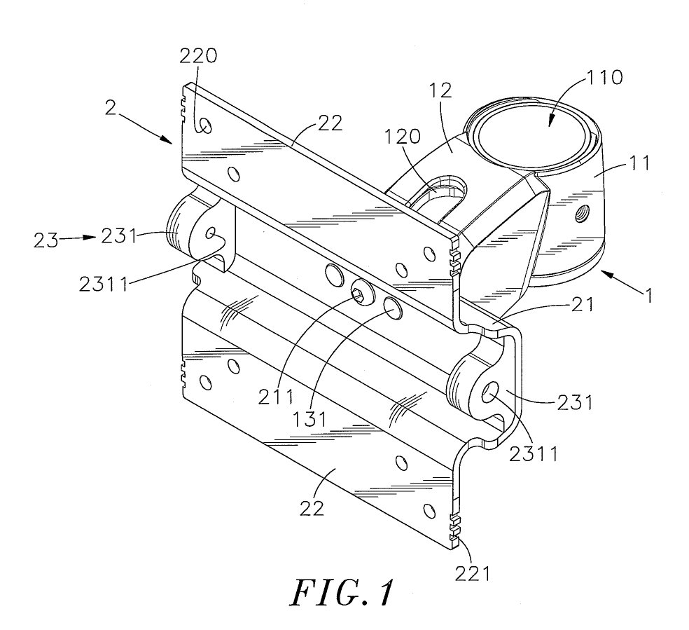

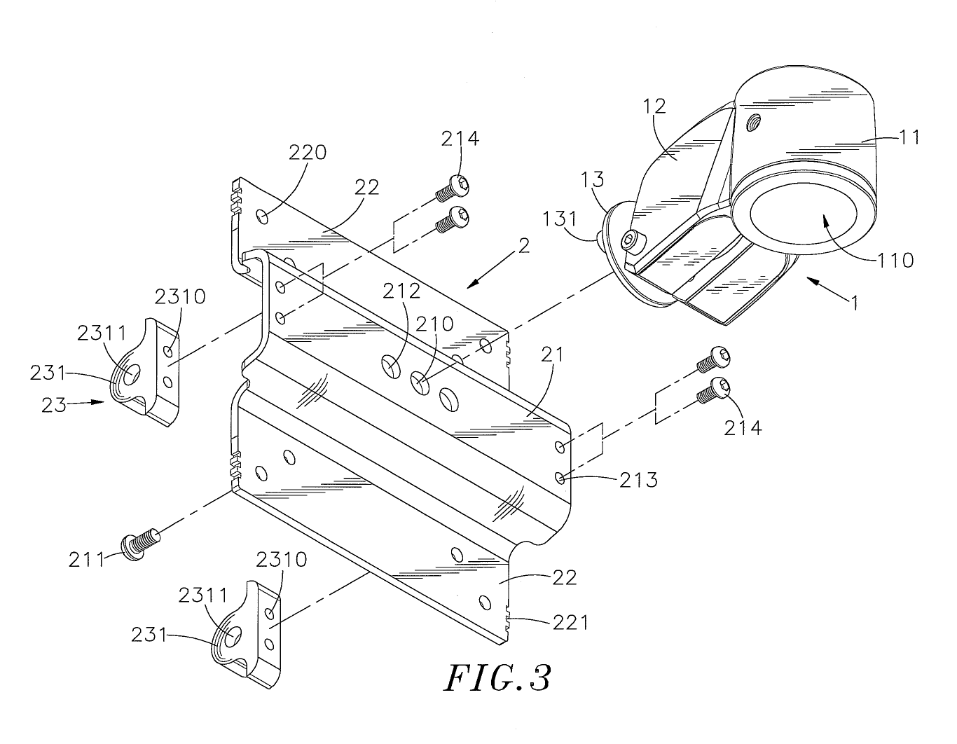

Referring to FIGS. 1-3, a display screen mounting structure in accordance with a first embodiment of the present invention is shown comprising a mounting frame unit 1 and a support frame unit 2.

The mounting frame unit 1 comprises a base member 11, an axle hole 110 axially cut through top and bottom sides of the base member 11, a forked support arm 12 perpendicularly extended from the periphery of the base member 11, an opening 120 defined in the forked front end of the forked support arm 12, a connection rod member 121 vertically pivotally mounted in the opening 120 in the forked front end of the forked support arm 12, a connection plate 13 fixedly connected to the outer end of the connection rod member 121 outside the forked support arm 12, a mounting screw hole 130 located on the center of the connection plate 13 and two pins 131 protruded from the outer wall of the connection plate 13 at two opposite sides relative to the mounting screw hole 130.

The support frame unit 2 comprises a channel frame 21, two shoulder plates 22 respectively symmetrically extended from two opposite lateral sides of the channel frame 21, and a locating block set 23 mounted in the channel frame 21. The channel frame 21 has a center through hole 210 cut through the center of the channel frame 21 corresponding to the mounting screw hole 130 for the mounting of a screw 211, two pin holes 212 located on the channel frame 21 at two opposite sides relative to the mounting through hole 210 and adapted for receiving the pins 131, and a plurality of mounting through holes 213 symmetrically located near the two distal ends thereof. Each shoulder plate 22 has a plurality of friction teeth 221 respectively located the two distal ends thereof and a plurality of mounting through holes 220 cut through the front and back sides near the two distal ends for the mounting of respective screw nails 222. The locating block set 23 includes two locating blocks 231 respectively mounted in the channel frame 21 near two distal ends thereof. Each locating block 231 comprises a countersunk hole 2311 transversely extending through two opposite lateral sides thereof and a plurality of mounting screw holes 2310 located on the back side thereof.

During installation, press-fit the pins 131 of the connection plate 13 of the mounting frame unit 1 into the pin holes 212 of the channel frame 21 of the support frame unit 2 respectively, and then insert the screw 211 through the center through hole 210 of the channel frame 21 and drive the screw 211 into the mounting screw hole 130 of the connection plate 13, thereby fixedly fastening the mounting frame unit 1 and the support frame unit 2 together. When assembled, the support frame unit 2 can be biased with the connection plate 13 and the connection rod member 121 relative to the forked support arm 12 and the base member 11 to the desired angular position.

Further, the opening 120 defined in the forked front end of the forked support arm 12 can be configured for allowing biasing of the connection rod member 121 relative to the forked support arm 12 and the base member 11 within the range of 90-degrees, smaller than 90-degrees or greater than 90-degrees.

Further, according to this embodiment, screws 214 are respectively inserted through the mounting through holes 213 of the channel frame 21 and threaded into the mounting screw holes 2310 of the locating blocks 231 of the locating block set 23 to affix the locating block set 23 to the channel frame 21. Alternatively, the locating blocks 231 of the locating block set 23 can be formed integral with the channel frame 21, or separately made and then welded to the channel frame 21.

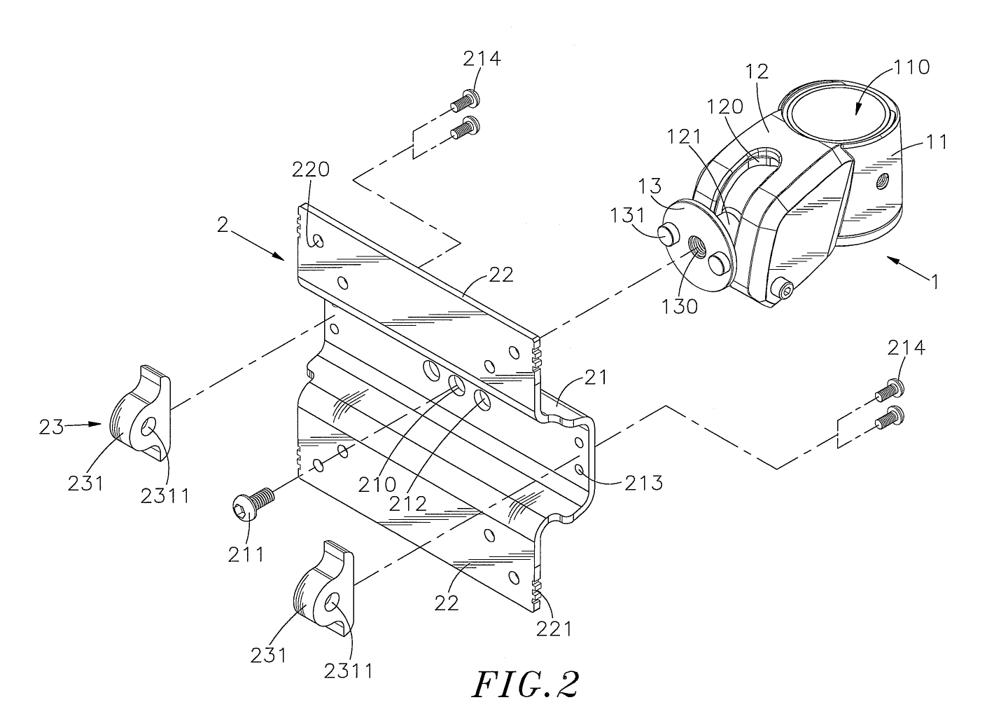

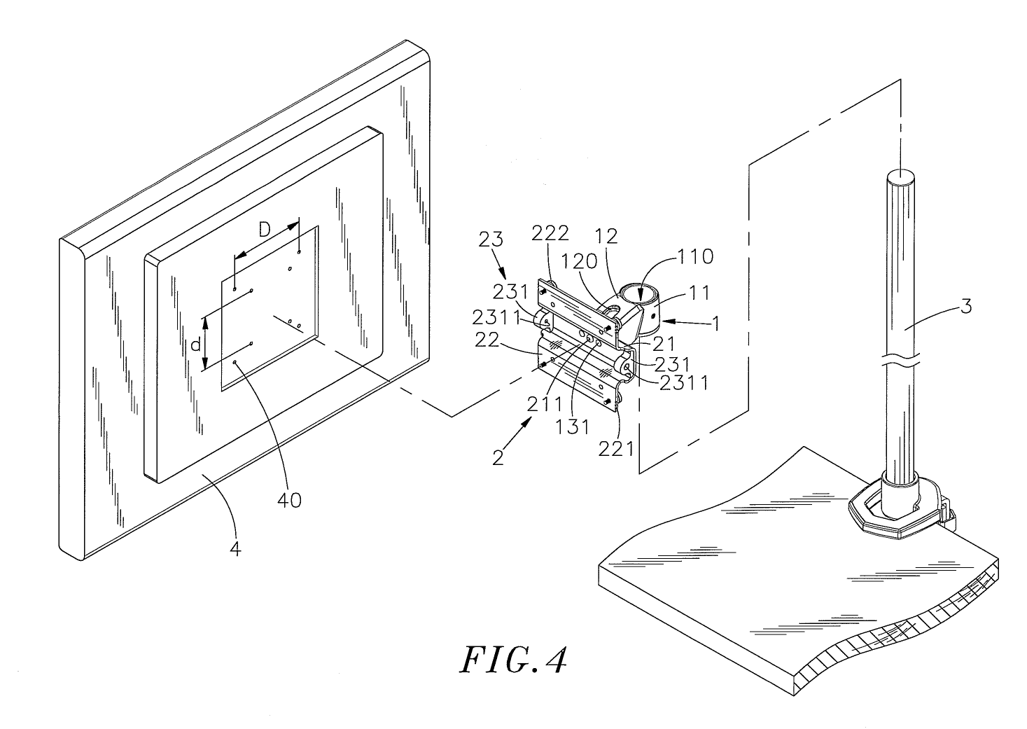

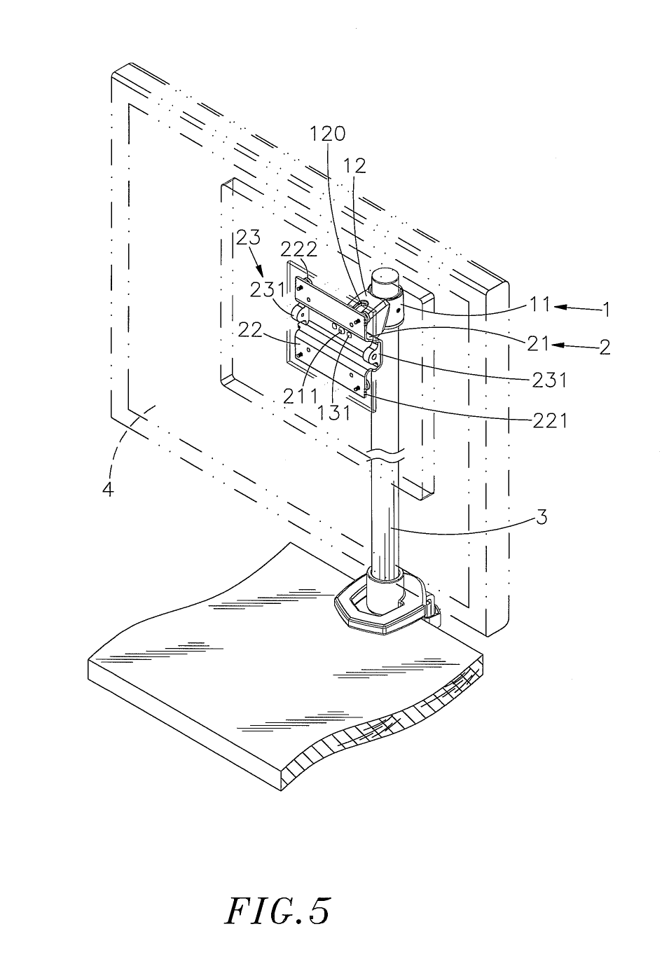

Referring to FIGS. 4 and 5 and FIGS. 2 and 3 again, during application of the display screen mounting structure, attach the base member 11 of the mounting frame unit 1 to an upright support bar 3 (of a stand). By means of the axle hole 110, the base member 11 of the mounting frame unit 1 can be conveniently attached to the upright support bar 3, and then locked thereto by a locking member (not shown) after adjustment of the elevation of the base member 11 of the mounting frame unit 1 relative to the upright support bar 3, and then insert respective screw nails 222 through the mounting through holes 220 of the shoulder plates 22 and driven the screw nails 222 into respective mounting holes 40 on the back wall of a display screen 4 to affix the display screen 4 to the support frame unit 2. Further, the mounting through holes 220 of the shoulder plates 22 are arranged into symmetrical pairs, and the two mounting through holes 220 of one same pair is kept at a predetermined distance subject to the arrangement of the mounting holes 40 on the back wall of the display screen 4. For example, the pitch d=75 mm×75 mm; the pitch D=75 mm×75 mm, or 100 mm×100 mm, or 200 mm×200 mm.

Further, the axle hole 110 of the base member 11 of the mounting frame unit 1 can be made having a circular cross section, rectangular cross section or polygonal cross section fitting the shape of the cross section of the upright support bar 3. Thus, the base member 11 can be smoothly moved along the upright support bar 3 to the desired elevation and then locked thereto.

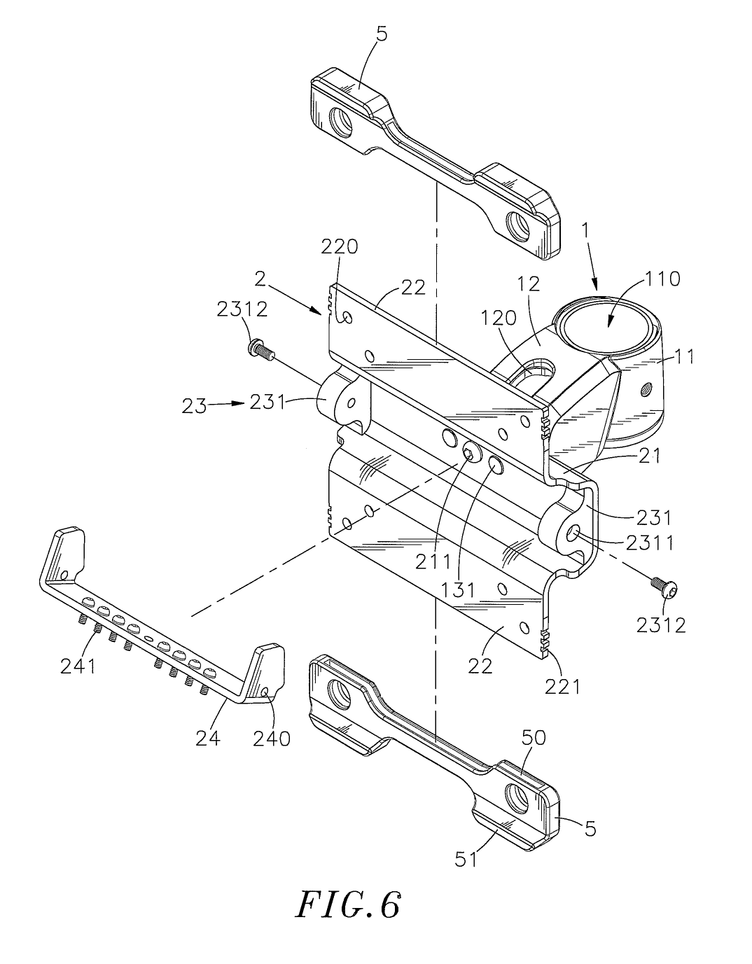

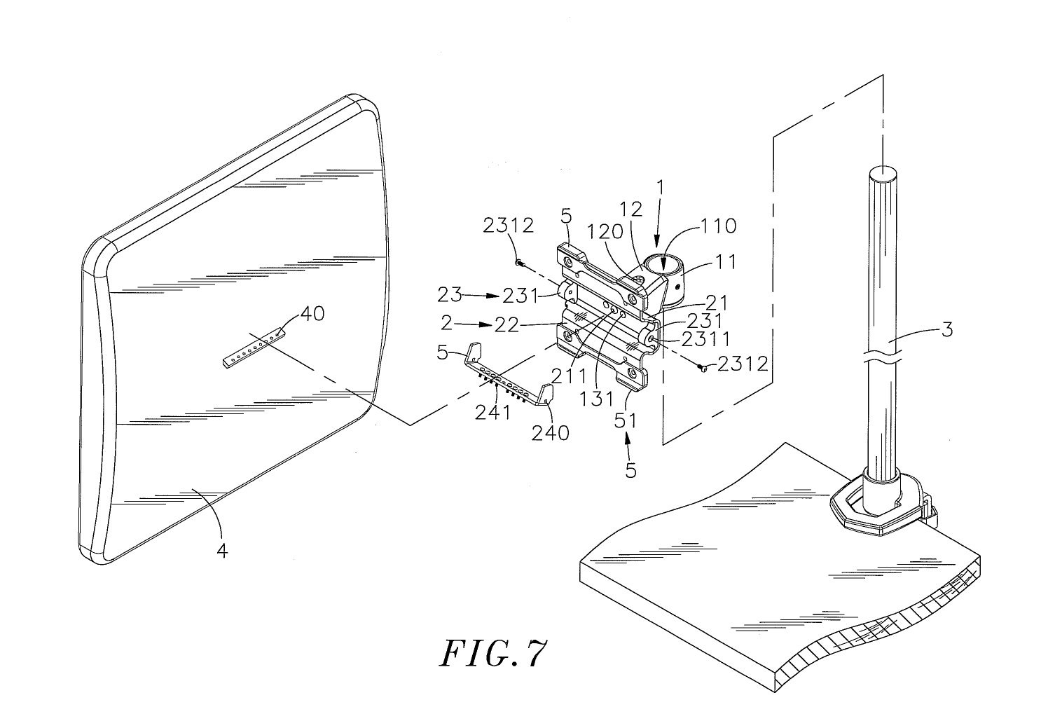

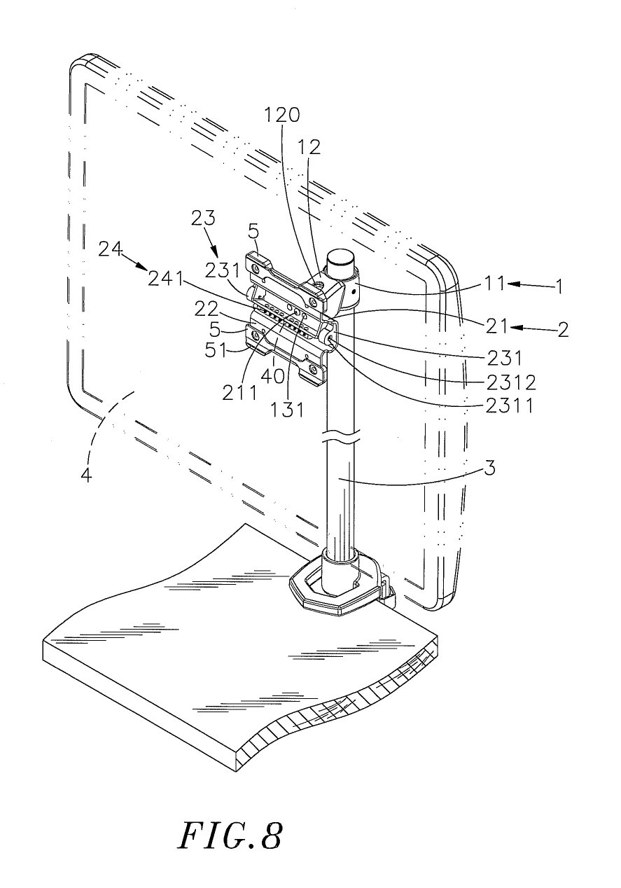

Referring to FIGS. 6-8, a display screen mounting structure in accordance with a second embodiment of the present invention is shown comprising a mounting frame unit 1 and a support frame unit 2. According to this second embodiment, the mounting frame unit 1 is exactly same as that of the aforesaid first embodiment. The support frame unit 2 of the display screen mounting structure in accordance with this second embodiment substantially similar to that of the aforesaid first embodiment with the exception that the support frame unit 2 of this second embodiment further comprises two cushion members 5 respectively capped on the shoulder plates 22, and a connection frame 24 connected between the two locating blocks 231 of the locating block set 23 for fastening to the back wall of a display screen 4. Each cushion member 5 has a mounting chamber 50 for receiving one shoulder plate 22, and a stop flange 51 perpendicularly extended from one lateral side thereof for stopping against the back wall of the display screen 4. By means of the mounting chamber 50, each cushion member 5 is capped on one respective shoulder plate 22 and firmly secured thereto subject to friction resistance between the respective friction teeth 221 and the inside wall of the mounting chamber 50. The connection frame 24 is a substantially U-shaped frame, having a mounting hole 240 located on each of the two angled distal ends thereof and respectively fastened to the countersunk hole 2311 on each of the locating blocks 231 of the locating block set 23 with a respective screw 2312 and a set of mounting screws (for example, 8 pcs of mounting screws) 241 arranged in a row between the two angled distal ends for fastening to respective mounting screw holes 40 (for example, 8 pcs of mounting screws holes) on the back wall of the display screen 4. As this second embodiment is basically same as the aforesaid first embodiment with the exception of the additional cushion members 5 and connection frame 24, one same tooling machine can be used for the fabrication of these two embodiments to fit different installation requirements, saving the cost.

During application, the axle hole 110 of the base member 11 of the mounting frame unit 1 is coupled to the upright support bar 3, and then the base member 11 is moved along the upright support bar 3 to adjust the display screen 4 to the desired elevation, and then lock the base member 11 to the upright support bar 3.

Further, the cushion members 5 that are respectively capped on the shoulder plates 22 of the support frame unit 2 can be selected from the group of rubber, flexible plastics and silicon rubber.

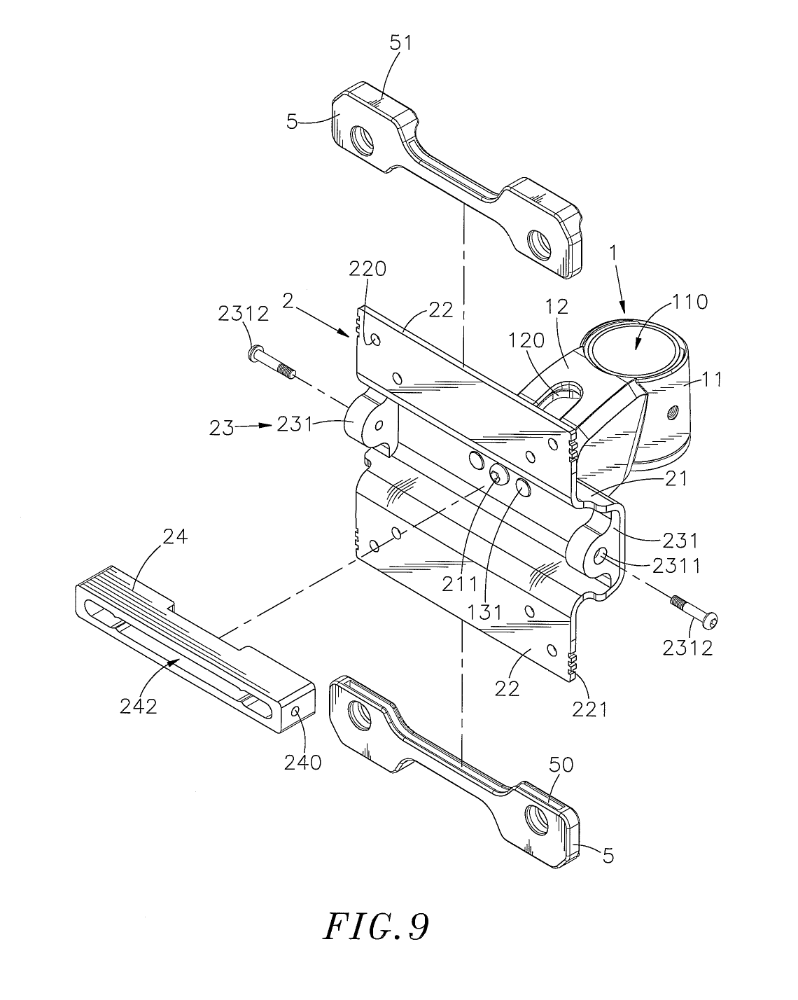

FIGS. 9˜11 illustrate a display screen mounting structure in accordance with a third embodiment of the present invention. This third embodiment is substantially similar to the aforesaid second embodiment with the exception of the structure of the connection frame 24. According to this embodiment, the connection frame 24 is a rectangular box frame for the mounting of a display screen 4 that has a substantially U-shaped bracket 41 located on the back wall thereof and a mounting screw hole 410 located on each of the two angled distal ends of the bracket 41. The connection frame 25 has a mounting hole 240 located on each of the opposite end walls thereof and a coupling chamber 242 defined between the opposite end walls and fitting the U-shaped bracket 41 of the display screen 4. During installation, insert the U-shaped bracket 41 of the display screen 4 coupling chamber 242 of the connection frame 24 to keep the mounting screw holes 410 of the bracket 41 in axial alignment with the mounting holes 240 of the connection frame 24 respectively, and then insert the respective screw 2312 into each mounting hole 240 and drive each screw 2312 into the associating mounting screw hole 410 to affix the connection frame 24 to the bracket 41 of the display screen 4.

During installation of this third embodiment, the axle hole 110 of the base member 11 of the mounting frame unit 1 is coupled to the upright support bar 3, and then the base member 11 is moved along the upright support bar 3 to adjust the display screen 4 to the desired elevation, and then lock the base member 11 to the upright support bar 3.

As stated above, the invention provides a display screen mounting structure consisting of a mounting frame unit 1 and a support frame unit 2, wherein the mounting frame unit 1 comprises a base member 11 vertically adjustably fastened to an upright support bar 3, a forked support arm 12 extended from the base member 11, a connection rod member 121 vertically pivotally mounted in an opening 120 in the forked front end of the forked support arm 12, a connection plate 13 fixedly connected to the outer end of the connection rod member 121 outside the forked support arm 12; the support frame unit 2 comprises a channel frame 21 fastened to the connection plate 13, two shoulder plates 22 respectively symmetrically extended from two opposite lateral sides of the channel frame 21 for the mounting of a display screen, and a locating block set 23 mounted in the channel frame 21 for the connection of a connection frame 24 for the mounting of a different model of display screen.

In conclusion, the display screen mounting structure of the present invention has advantages and features as follows:
1. By means of the base member 11, the mounting frame unit 1 can be vertically adjustably fastened to an upright support bar 3; by means of the locating block set 23, different designs of connection frames 24 can be selectively used for the mounting of a different model of display screen 4 on the support frame unit 2. Thus, one same tooling machine can be used for the fabrication of display screen mounting structures to fit different models of display screens 4, saving the cost.
2. When a consumer is going to replace an old display screen 4 with a new model of display screen 4, the display screen mounting structure can be kept for supporting the new model of display screen 4 by means of using a matching design of connection frame 24 to connect the new model of display screen 4 to the locating block set 23.

Although particular embodiments of the invention have been described in detail for purposes of illustration, various modifications and enhancements may be made without departing from the spirit and scope of the invention. Accordingly, the invention is not to be limited except as by the appended claims.

What the invention claimed is:

1. A display screen mounting structure, comprising:
a mounting frame unit comprising a base member for fastening to an upright support, a forked support arm perpendicularly extended from the periphery of said base member, an opening defined in a front end of said forked support arm, a connection rod member vertically pivotally mounted in said opening in said front end of said forked support arm, and a connection plate fixedly connected to an outer end of said connection rod member outside said forked support arm;
a support frame unit comprising a channel frame fastenable to said connection plate, two shoulder plates respectively symmetrically extended from two opposite lateral sides of said channel frame and adapted for supporting a display screen, and a locating block set mounted in said channel frame between said shoulder plates.

2. The display screen mounting structure as claimed in claim 1, wherein said base member comprises an axle hole axially cut through top and bottom sides thereof configured to fit the cross section of an upright support for mounting.

3. The display screen mounting structure as claimed in claim 1, wherein the opening defined in the front end of said forked support arm is configured for allowing biasing of said connection rod member relative to said forked support arm and said base member within a predetermined angle less than 90-degrees

4. The display screen mounting structure as claimed in claim 1, wherein the opening defined in the front end of said forked support arm is configured for allowing biasing of said connection rod member relative to said forked support arm and said base member within a predetermined angle greater than 90-degrees.

5. The display screen mounting structure as claimed in claim 1, wherein said channel frame of said support frame unit comprises a center through hole cut through the center thereof and at least one pin hole disposed adjacent to said center through hole; said connection plate of said mounting frame unit comprises a center mounting screw hole fastened to said center through hole of said channel frame by a screw and at least one pin press-fitted into said at least one pin hole.

6. The display screen mounting structure as claimed in claim 5, wherein the number of said at least one pin hole of said channel frame is 2, and the two pin holes are disposed at two opposite sides relative to said center through hole; the number of said at least one pin of said connection plate is 2, and the two pins of said connection plate are respectively press-fitted into the two pin holes of said channel frame.

7. The display screen mounting structure as claimed in claim 1, wherein said locating block set comprises two locating blocks fixedly mounted in said channel frame near two distal ends thereof between said shoulder plates.

8. The display screen mounting structure as claimed in claim 7, wherein said two locating blocks are welded said channel frame near two distal ends thereof between said shoulder plates.

9. The display screen mounting structure as claimed in claim 7, wherein said two locating blocks are detachably affixed to said channel frame with fastening members.

10. The display screen mounting structure as claimed in claim 7, wherein said support frame unit further comprises a connection frame connected between said two locating blocks, each said locating block having a countersunk hole, said connection frame having a mounting hole located on each of two distal ends thereof and respectively fastened to the countersunk hole of each of said two locating blocks by a respective screw.

11. The display screen mounting structure as claimed in claim 10, wherein said connection frame is a substantially U-shaped frame carrying a set of mounting screws that are arranged in a row between two angled distal ends of said connection frame for fastening to respective mounting screw holes on the back wall of a display screen.

12. The display screen mounting structure as claimed in claim 10, wherein said connection frame is a rectangular box frame for fastening to a U-shaped bracket at a back side of a display screen, comprising a coupling chamber defined between two opposite end walls thereof and fitting the U-shaped bracket of the display screen.

13. The display screen mounting structure as claimed in claim 1, wherein said support frame unit further comprises two cushion members respectively capped on said shoulder plates, each said cushion member comprising a mounting chamber for receiving one said shoulder plate and a stop flange perpendicularly extended from one lateral side thereof for stopping against the back wall of the display screen to be supported on said support frame unit; each said shoulder plate comprises a plurality of friction teeth respectively located two distal ends thereof for friction engagement with an inside wall of the associating cushion member.

14. The display screen mounting structure as claimed in claim 13, wherein said cushion members are made of a material selected from the group of rubber, flexible plastics and silicon rubber.
